(19) United States
(12) Patent Application Publication
(10) Pub. No.: US 2025/0356075 A1
(43) Pub. Date: Nov. 20, 2025

(54) ITERATIVE REDESIGN OF PRESSURE-CONTROL COMPONENT DESIGNS BASED ON A CONDUIT POOL

(71) Applicant: Schlumberger Technology Corporation, Sugar Land, TX (US)

(72) Inventors: Yaou Wang, Sugar Land, TX (US); Christopher Nault, Sugar Land, TX (US); Matthew Givens, Houston, TX (US); Terry Clancy, Sugar Land, TX (US)

(21) Appl. No.: 18/663,348

(22) Filed: May 14, 2024

(51) Int. Cl. G06F 30/20; E21B 33/06

(52) U.S. Cl. CPC G06F 30/20; E21B 33/062; E21B 2200/20

(57) ABSTRACT

A method of designing pressure-control components including inputting a first design into a simulation program. Inputting a conduit pool into the simulation program. Automatically testing the first design with respect to the conduit pool using the simulation program. Identifying one or more points of failure of the first design based on the test. Modifying the design based on the one or more points of failure and testing the modified design with respect to the conduit pool.

### BACKGROUND

This section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

A blowout preventer (BOP) is installed on a wellhead to seal and control an oil and gas well during various operations. For example, during drilling operations, a drill string may be suspended from a rig through the BOP into a wellbore. A drilling fluid is delivered through the drill string and returned up through an annulus between the drill string and a casing that lines the wellbore. In the event of a rapid invasion of formation fluid in the annulus, commonly known as a “kick,” the BOP may be actuated to seal the annulus and to contain fluid pressure in the wellbore, thereby protecting well equipment positioned above the BOP.

Designing BOPs is time and resource intensive. There is a need in the art to decrease development time and costs associated with creating new BOP designs.

### SUMMARY

Aspects of the present disclosure provide systems, apparatus, and methods for designing pressure-control components.

In one aspect, a method of designing a ram comprises inputting a first ram design into a simulation program. The method further comprises The method further comprises inputting a conduit pool into the simulation program, the conduit pool including a first conduit and one or more properties of the first conduit. The method further comprises automatically testing the first ram design with respect to the first conduit in the conduit pool using the simulation program. The testing includes generating a first finite element analysis model based on the one or more properties of the first conduit and the first ram design; simulating an operation of the first ram design using the first finite element analysis model to generate a first simulated maximum shear pressure and a first simulated deformation; and determining that the first ram design failed the test when at least one of the first simulated maximum shear pressure exceeds a shear pressure threshold or the first simulated deformation exceeds a deformation threshold. The method further comprises modifying the first ram design to create a second ram design after determining that the first ram design failed the test. The method further comprises automatically testing the second ram design with respect to the first conduit in the conduit pool using the simulation program.

In one aspect, a non-transitory, computer-readable medium storing instructions of a simulation program executable by a processor of a computer system. The instructions include testing, for a first time, a first ram design input into the processor with respect to a first conduit in a conduit pool input into the processor using the simulation program. The testing includes: generating a first finite element analysis model based on the first ram design and one or more properties of the first conduit; simulating an operation of the first ram design using the first finite element analysis model to generate first simulated shear pressure data and first simulated deformation data, the first simulated shear pressure data includes a first maximum simulated shear pressure and the first simulated deformation data includes a first simulated deformation; determining that: the first ram design failed the first test when at least one of a first simulated maximum shear pressure exceeds a shear pressure threshold or the first simulated deformation exceeds a deformation threshold; or that the first ram design passed the first test when the first simulated maximum shear pressure is less than the shear pressure threshold and the first simulated deformation is less than the deformation threshold. The instructions further include testing, for a second time, the first ram design with respect to a second conduit in the conduit pool input into the processor using the simulation program upon determining that the first ram passed the first test. The instructions further include modifying the first ram design to create a second ram design after determining that the first ram design failed the first test and testing the second ram design with respect to the first conduit in the conduit pool.

In one aspect, a non-transitory, computer-readable medium storing instructions of a simulation program executable by a processor of a computer system. The instructions include receiving an first ram design. The instructions further include receiving a conduit pool, the conduit pool including one or more properties of a plurality of conduits. The instructions further include changing the first ram design to output a second ram design, comprising: testing the first ram design against the conduit pool, wherein the first ram design fails the test if a first maximum simulated shear pressure exceeds a shear pressure threshold or a first simulated deformation exceeds a deformation threshold for any of the conduits in the conduit pool, the test including: generating a first finite element analysis model based on one conduit in the conduit pool and the first ram design; and simulating an operation of the first ram design using the first finite element analysis model to generate first simulated shear pressure data and first simulated deformation data, the first simulated shear pressure data includes the first simulated maximum shear pressure and the first simulated deformation data includes the first simulated deformation; analyzing at least one of the first simulated shear pressure data or the first simulated deformation data; identifying one or more points of failure of the first ram design based on the analysis of the at least one of simulated shear pressure data or first simulated deformation data; and modifying the first ram design to create a second ram design based on the at least one or more identified points of failure of the first ram design.

The following description and the appended figures set forth certain features for purposes of illustration.

### BRIEF DESCRIPTION OF DRAWINGS

The appended figures illustrate only exemplary embodiments and are therefore not to be considered limiting of the scope of the disclosure, as the disclosure may admit to other equally effective embodiments.

FIG. 1 is a block diagram of a drilling system for mineral extraction, in accordance with an embodiment of the present disclosure.

FIG. 2 is a cross-sectional top view of a portion of a blowout preventer (BOP) that may be used in the drilling system of FIG. 1, in accordance with an embodiment of the present disclosure.

FIG. 3 is a front isometric view of a component, namely an upper ram, which may be used in the BOP of FIG. 2, in accordance with an embodiment of the present disclosure.

FIG. 4 is a front isometric view of another component, namely a lower ram, that may be used in conjunction with the upper ram of FIG. 3 and the BOP of FIG. 2, in accordance with an embodiment of the present disclosure;

FIG. 5 is a graph illustrating experimentally determined shear pressure data collected during laboratory testing of a BOP shear ram design, in accordance with an embodiment of the present disclosure.

FIG. 6 is an example computer-aided design (CAD) model of a simulated testbed for testing a BOP shear ram design, in accordance with an embodiment of the present disclosure.

FIG. 7 is an example finite-element analysis (FEA) model of the simulated testbed of FIG. 6, in accordance with an embodiment of the present disclosure.

FIG. 8 is a three-dimensional (3D) visualization of conduit and shear ram deformation from a simulated shearing process, in accordance with an embodiment of the present disclosure.

FIG. 9 is a shear pressure curve indicating the shearing pressure over time throughout a simulated shearing process, in accordance with an embodiment of the present disclosure.

FIG. 10 is a flow diagram illustrating a process whereby a computer-aided engineering (CAE) toolkit configures and performs a simulation of a pressure-controlling component design, in accordance with an embodiment of the present disclosure.

FIG. 11 is an example of a graphical user interface (GUI) of the CAE toolkit, in accordance with an embodiment of the present disclosure.

FIG. 12 is an example CAE system model generated by the CAE toolkit for an example BOP shear ram design, in accordance with an embodiment of the present disclosure.

FIG. 13 illustrates a 3D deformation visualization of a ram design and conduit based on a simulation performed by the CAE toolkit based on the example CAE system model of FIG. 12, in accordance with an embodiment of the present disclosure.

FIG. 14 illustrates a 3D deformation visualization of a portion of a shear ram based on a simulation performed by the CAE toolkit based on the example CAE system model of FIG. 12, in accordance with an embodiment of the present disclosure.

FIG. 15 illustrates a shear pressure curve based on a simulation performed by the CAE toolkit based on the example CAE system model of FIG. 12, in accordance with an embodiment of the present disclosure.

FIG. 16 illustrates a method of automatically redesigning an input pressure-control component design based on testing against a conduit pool, in accordance with an embodiment of the present disclosure.

FIG. 17 illustrates a graph showing the results of iterative redesigning of a shear ram design, in accordance with an embodiment of the present disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Aspects of the present disclosure provide systems, apparatus, and methods for automatically simulating an operation of a pressure-control component design against a conduit pool and using the simulated shear data and simulated deformation data gathered during the simulation to automatically redesign the pressure-control component.

One or more specific embodiments of the present disclosure will be described below. These described embodiments are only exemplary of the present disclosure. Additionally, in an effort to provide a concise description of these exemplary embodiments, all features of an actual implementation may not be described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

As discussed below, a ram BOP includes two shear rams that, under certain conditions, are moved toward one another to shear a conduit (e.g., a drilling pipe) and to form a seal to block fluid flow across the ram BOP. Since this shearing process occurs within the BOP body, the shearing process is not readily observable. As such, multiple laboratory tests are typically performed on a shear ram design to verify the operation of the ram BOP and to verify the shearing pressure of the conduits. It is presently recognized that this extensive laboratory testing is both expensive and time-consuming. To reduce the volume of laboratory testing performed, computer-aided engineering (CAE) methods may be applied to simulate the shearing process during ram BOP design. However, it is also presently recognized that CAE methods typically involve significant effort of an experienced modeling and simulation engineer to set up the model, run the simulation, and post-process the results into a desirable form. As such, while CAE methods are generally cheaper than laboratory testing, applying a typical CAE method is time-consuming and involves specialized skills and training.

With the foregoing in mind, present embodiments are generally directed to a CAE toolkit that streamlines and automates aspects of a CAE simulation to validate the designs of pressure-controlling components, such as BOP rams. As discussed below, the CAE toolkit enables a designer to provide a model of a pressure-controlling component, and to provide system property values that describe aspects of the system to be modeled (e.g., conduit materials, conduit dimensions, well dimensions). One of these inputs may be a pipe pool including one or more exemplary pipes with different characteristics to ensure that the pressure-controlling component will function properly for a variety of pipes. Based on these inputs, the CAE toolkit generates a model for the system that includes the pressure-controlling component, as well as any other components that will be part of the simulation. Additionally, the CAE toolkit can also automatically generate a finite element analysis (FEA) model from the system model, and then use the FEA model to perform a simulation of the pressure-controlling component during operation. The FEA model may generate simulated shear data and simulated deformation data. For example, when used to simulate the operation of a shear ram BOP, the outputs of the simulation may include a three-dimensional (3D) model that enables visualization of predicted deformation of the conduit and/or the shear rams as a result of the simulated conduit shearing process. The outputs may also include a shear force curve that predicts the shear force applied to the BOP shear rams over the simulated conduit shearing process. In certain embodiments, the CAE toolkit can also automatically perform post-processing of the outputs of the simulation, for example, to convert the shear force curve into a shear pressure curve. As such, the disclosed CAE toolkit may enable a designer with no training or experience with CAE or FEA techniques to perform and automate simulations of the operation of a pressure-controlling component design. The design may use the simulated data, such as the 3D model, to identify points of failure of a pressure-controlling component design which can then be used to update the design. By enabling the performance of various designs to be simulated and compared under real and complex well scenarios, the CAE toolkit enables the designer to more easily and more quickly optimize the design of the component. Additionally, the CAE toolkit may automate the pressure-control component redesign in certain scenarios, such as using the shear data and/or the deformation data to redesign at least one portion of the ram design. This updated ram design is then automatically tested. In other words, the CAE toolkit may iteratively redesign an initial pressure-control component design input by the CAE toolkit to produce a final ram design with desired qualities.

To facilitate discussion, the CAE toolkit is described in the particular context of the simulated testing the design of shear rams of a shear ram BOP. However, it should be appreciated that the systems and methods for simulated testing of component designs may be adapted for the design and testing of other pressure-controlling components or equipment, such as another component of the BOP for the drilling system and/or another component of another device for any type of system (e.g., drilling system, production system). The disclosed CAE toolkit is one exemplary simulation program that can be used to simulate testing of a design of a pressure-controlling component, validate the design, and modify the design based on simulated data obtained during the simulated testing.

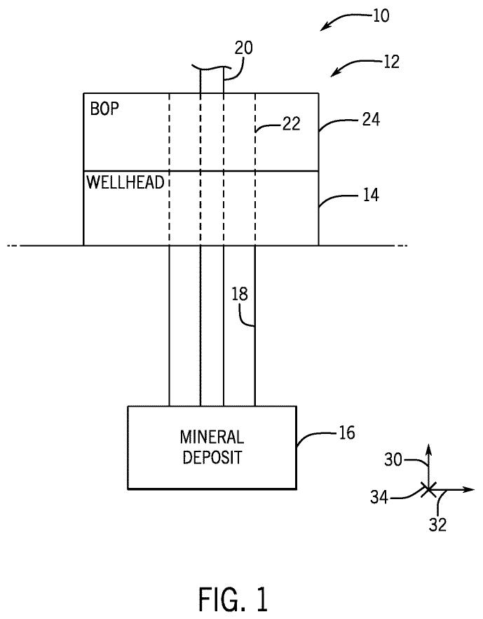

With the foregoing in mind, FIG. 1 is a block diagram of an embodiment of a drilling system 10 for mineral extraction. The drilling system 10 may be configured to drill (e.g., circulate drilling mud and take drilling cuttings up to surface) for the eventual extraction of extract various minerals and natural resources, including hydrocarbons (e.g., oil and/or natural gas), from the earth and/or to inject substances into the earth. The drilling system 10 may be a land-based system (e.g., a surface system) or an offshore system (e.g., an offshore platform system).

As shown, a BOP stack 12 may be mounted to a wellhead 14, which is coupled to a mineral deposit 16 via a wellbore 18. The wellhead 14 may include or be coupled to any of a variety of other components such as a spool, a hanger, and a “Christmas” tree. The wellhead 14 may return drilling fluid or mud toward a surface during drilling operations, for example. Downhole operations are carried out by a conduit 20 (e.g., drill string) that extends through a central bore 22 of the BOP stack 12, through the wellhead 14, and into the wellbore 18.

As discussed in more detail below, the BOP stack 12 may include one or more BOPs 24 (e.g., ram BOPs), and components (e.g., rams) of the one or more BOPs 24 may be designed and tested using the CAE toolkit disclosed herein. To facilitate discussion, the BOP stack 12 and its components may be described with reference to a vertical axis or direction 30, an axial axis or direction 32, and/or a lateral axis or direction 34.

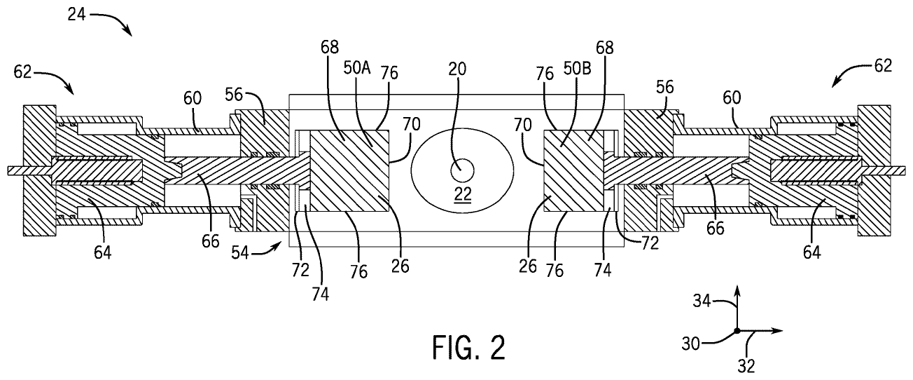

FIG. 2 is a cross-sectional top view of a portion of an exemplary embodiment of the BOP 24 that may be used in the drilling system 10 of FIG. 1, in accordance with an embodiment of the present disclosure. As shown, the BOP 24 includes opposed rams 50, including upper ram 50A and lower ram 50B, also generally referred to herein as pressure-controlling components 26 of the BOP 24. In the illustrated embodiment, the opposed rams 50 are in an open configuration 54 of the BOP 24 in which the opposed rams 50 are withdrawn from the central bore 22, do not contact the conduit 20, and/or do not contact one another.

As shown in FIG. 2, the BOP 24 includes a bonnet flange or housing 56 surrounding the central bore 22. The bonnet flange 56 is generally rectangular in the illustrated embodiment, although the bonnet flange 56 may have any cross-sectional shape, including any polygonal shape and/or annular shape. Bonnet assemblies 60 are mounted on opposite sides of the bonnet flange 56 (e.g., via threaded fasteners). Each bonnet assembly 60 includes an actuator 62, which may include a piston 64 and a connecting rod 66. The actuators 62 may drive the opposed rams 50 toward one another along the axial axis 32 to reach a closed position in which the opposed rams 50 are positioned within the central bore 22, contact and/or shear the conduit 20 to seal the central bore 22, and/or contact one another to seal the central bore 22.

Each of the opposed rams 50 may include a body section 68 (e.g., ram body), a leading surface 70 (e.g., side, portion, wall) and a rearward surface 72 (e.g., side, portion, wall, rearmost surface). The leading surfaces 70 may be positioned proximate to the central bore 22 and may face one another when the opposed rams 50 are installed within the housing 56. The rearward surfaces 72 may be positioned distal from the central bore 22 and proximate to a respective one of the actuators 62 when the opposed rams 50 are installed within the housing 56. The leading surfaces 70 may be configured to couple to and/or support sealing elements (e.g., elastomer or polymer seals) that are configured to seal the central bore 22 in the closed position, and the rearward surfaces 72 may include an attachment interface 74 (e.g., recess) that is configured to engage with the connecting rod 66 of the actuator 62. The body section 68 also includes lateral surfaces 76 (e.g., walls) that are on opposite lateral sides of the body section 68 and that extend along the axial axis 32 between the leading surface 70 and the rearward surface 72. In FIG. 2, the opposed rams 50 have a generally rectangular shape to facilitate discussion; however, it should be appreciated that the opposed rams 50 may have any of a variety of shapes or features (e.g., curved portions to seal against the conduit 20, edges to shear the conduit 20).

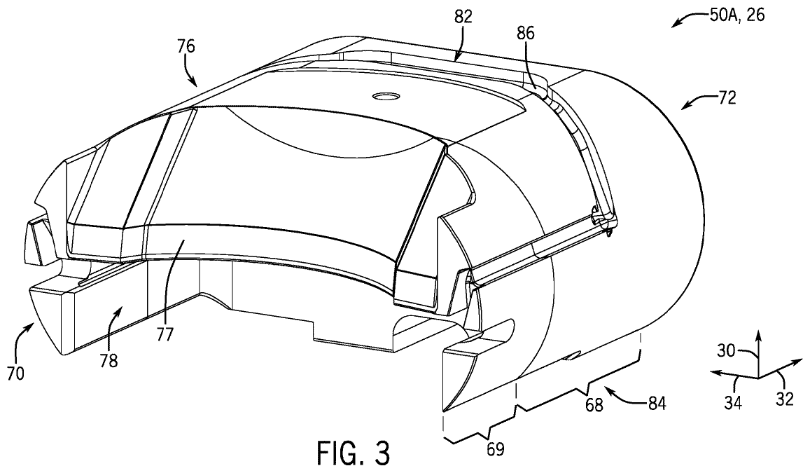

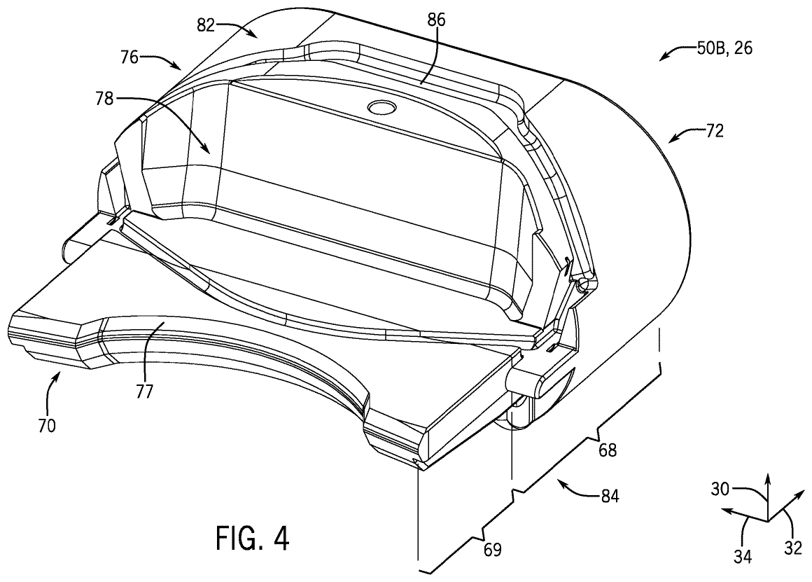

FIG. 3 is a front isometric view of an exemplary embodiment of the upper ram 50A. FIG. 4 is a front isometric view of an exemplary embodiment of the lower ram 50B. The upper ram 50A and lower ram 50B may be used together as pressure-controlling components 26 in the embodiment of the BOP 24 shown in FIG. 2. As illustrated in FIGS. 3 and 4, the pressure-controlling components 26 each include the body section 68 and a blade section 69. Each blade section 69 includes the leading surface 70, while the body section 68 includes the rearward surface 72 of the rams 50A,B. Because the rams 50A,B of FIGS. 3 and 4 are shear rams, each blade section 69 includes a respective edge portion 77 that is formed in the leading surface 70 and that extends along the lateral axis 34 of each of the rams 50. In a closed configuration, the respective edge portions 77 of the upper ram 50A and the lower ram 50B are configured to shear the conduit 20 and/or support the seal elements that seal against the central bore 22 of the BOP illustrated in FIG. 2. However, it should be appreciated that the rams 50 may have any of a variety of other configurations (e.g., the rams 50 may be pipe rams that lack the respective edge portions 77). The blade section 69 of each of the rams 50 of FIGS. 3 and 4 also includes a leading cutout 78 formed in the leading surfaces 70 (e.g., positioned above and below the respective edge portion 77 along the vertical axis 30). The leading surface 70, the rearward surface 72, the lateral surfaces 76, a top surface 82 (e.g., top-most surface), and a bottom surface 84 (e.g., bottom-most surface) may be considered the respective outer surfaces of the rams 50. For the illustrated rams 50, the outer surfaces include grooves or channels 86. In certain embodiments, at least a portion of these grooves may be sealing grooves designed to receive or interface with a polymeric material (e.g., an elastomeric seal), while a portion of these grooves may be sliding grooves designed to receive a slide along a metallic extension during operation of the BOP.

### Laboratory Testing of Pressure-Controlling Components

As noted above, when a pressure-controlling component, such as a BOP shear ram, is being designed, a portion of the design process is typically dedicated to performing laboratory testing of the design in a testbed to experimentally verify that the component operates as intended. For example, a shear ram design may be manufactured and loaded into a testbed that physically simulates the BOP body and the conditions of the wellbore. As such, the testbed enables the pressure-controlling components to be physically tested to verify that the design can operate as intended in real and complex well conditions.

For a BOP shear ram design, laboratory testing can be performed to verify that the shearing process can be completed in the testbed, to experimentally determine the shearing pressure applied to the shear rams throughout the shearing process, and experimentally observe deformation of the conduit and the shearing rams as a result of the shearing process. In general, multiple lab test runs are performed using all types (e.g., dimensions, materials) of conduits (e.g., drill pipes) that are expected to be used in combination with the shear ram design.

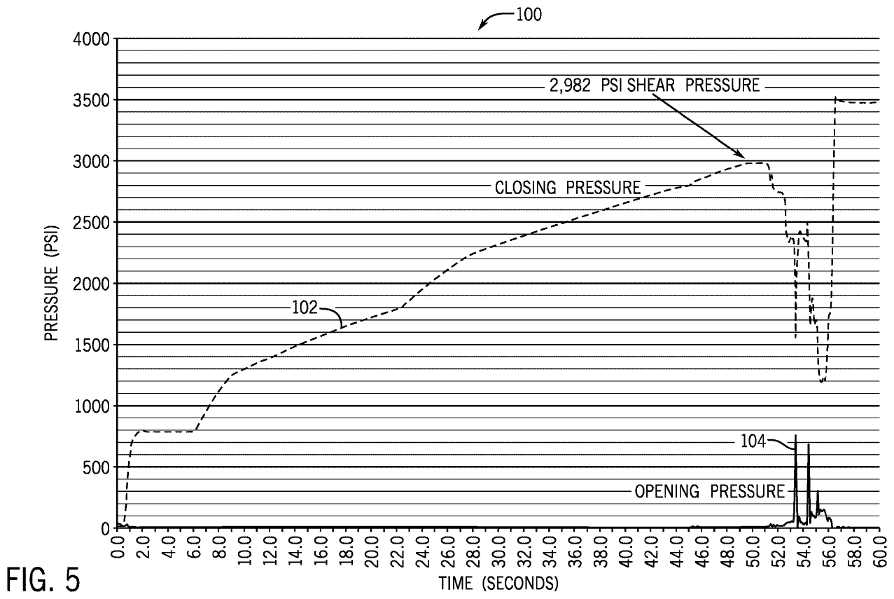

During laboratory testing of a shear ram design, shear pressure measurements are collected throughout the shearing process. Once the shear pressure test is complete, the conduit shearing cross-section and the shear rams are examined and deformations are recorded. FIG. 5 is a graph 100 illustrating experimentally determined shear pressure data collected during laboratory testing of a BOP shear ram design. The graph 100 includes an upper curve 102 that indicates the closing pressure (e.g., hydraulic pressure) applied to the shear rams during the shear pressure test, and includes a lower curve 104 that indicates the opening pressure applied to separate the BOP shear rams once the conduit has been sheared. For this example laboratory shear test, the upper curve 102 indicates a shear pressure of 2,982 pounds per square inch (psi), or approximately 3,000 psi.

However, it is presently recognized that performing this laboratory testing as part of the design process of pressure-controlling components introduces undesired inefficiencies to the design process. For example, when a shear ram design fails a shearing test during laboratory testing, then the design is typically modified or replaced by another shear ram design, and then all of the laboratory testing is repeated on the modified design. This design process is typically repeated until the design of the pressure-controlling component successfully passes all laboratory tests. Given that performing laboratory shearing tests may involve months of lead time and thousands of dollars in costs to be prepared and performed for each pressure-controlling component design, it is presently recognized that relying on laboratory testing for design testing and validation as part of a design process is inefficient and costly. That is, while laboratory testing still serves a useful role in verifying the operation of finalized pressure-controlling component designs prior to implementation, it is presently recognized that it would be advantageous to be able to test and verify the operation of these designs in an earlier stage of the design process with considerably less development time and cost. In other words, simulating a test of a pressure-controlling component and redesigning the pressure-component, in an iterative fashion, to create a design worth of laboratory testing significantly reduces development time and cost.

### CAE/FEA Modeling of Pressure-Controlling Component Designs

It is presently recognized that implementing a simulation program (e.g. CAE) based method to validate pressure-controlling component designs during a pressure-controlling component design process can offer advantages over relying solely on laboratory testing. For example, in a simulation program-based method, a FEA model may be constructed to simulate the shearing process for a BOP shear ram design. Such FEA models can be used to generate a 3D visualization of the simulated shearing process and predict shearing force applied to the shearing rams throughout the shearing process.

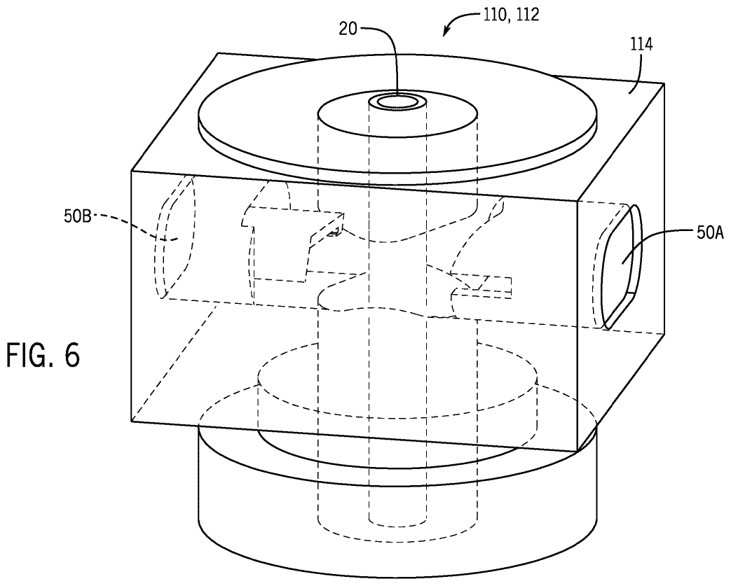

For example, FIG. 6 illustrates an embodiment of a system model 110 (e.g., CAD system model) of a simulated testbed 112. For the illustrated embodiment, the simulated testbed 112, which includes a BOP body 114 (e.g., BOP package or casing), shear rams 50 (e.g., upper shear ram 50A and lower shear ram 50B), and conduit 20. Prior to the present disclosure, a modeling and simulation engineer might construct a FEA model based on the system model 110 of the simulated testbed 112 to simulate the shearing process. As discussed below, using the disclosed CAE toolkit, a designer or operator with no knowledge or expertise in FEA modeling or simulation may generate an FEA model to perform simulated testing of pressure-controlling component designs.

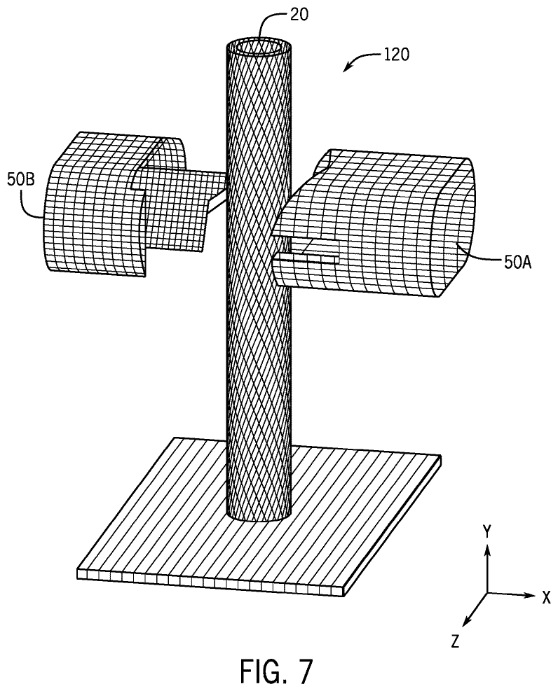

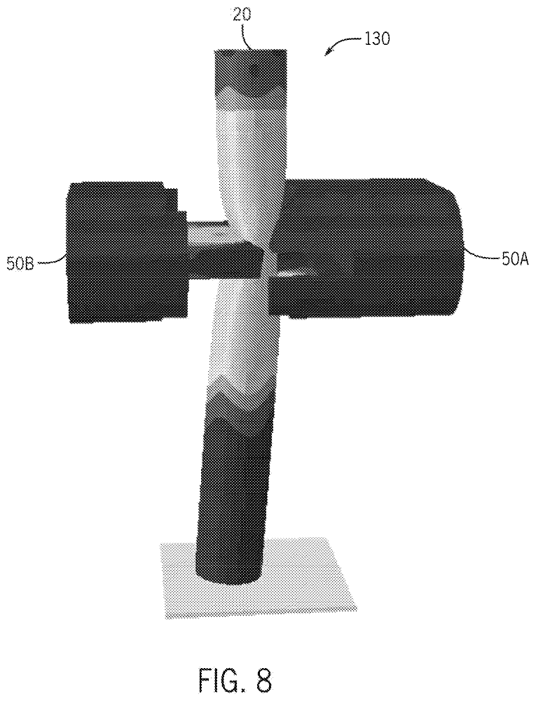

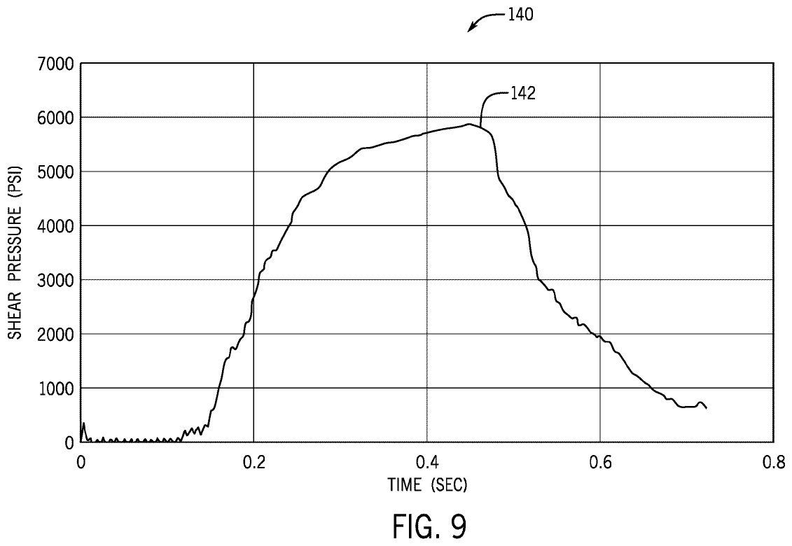

FIG. 7 illustrates an embodiment of a FEA model 120 of the simulated testbed 112 of FIG. 6. For the embodiment illustrated in FIG. 7, the FEA model 120 includes only the shear rams 50, and the conduit 20 for the illustrated embodiment. In the illustrated FEA model 120, the conduit 20 is supported from the bottom, and the shear rams 50 are configured to move toward each other to shear the conduit 20 during a shearing process. When the conduit 20 breaks during the simulation, the conduit 20 is highly deformed and is deleted from the FEA model 120 in some embodiments. The FEA model 120 is used to generate shear and deformation data. For example, the FEA model 120 determines the conduit deformation, ram deformation, and shearing force throughout the entire simulated shearing process. FIG. 8 is a 3D visualization 130 of deformation and internal strain in the conduit 20 and shear rams 50 during a portion of the simulated shearing process, as predicted by the FEA model 120. FIG. 9 is a shear pressure graph 140 for the simulated shearing process illustrated in FIG. 8, which shows the shear pressure applied to the shear rams 50 during the simulated shearing process. The shear pressure graph 140 includes a shear pressure curve 142 that predicts a maximum shearing pressure of 6000 psi for the example simulated shearing process.

However, it is presently recognized that performing FEA simulation to test designs as part of a design process of pressure-controlling components also presents challenges. For example, FEA simulations typically involve significant effort on the part of the modeling and simulation engineer. That is, prior to the present disclosure, a modeling and simulation engineer would have a substantial amount of training and experience in generating CAE/FEA models, and would spend a substantial amount of time setting up the model, running the simulation, and post-processing the results. As such, prior to the present disclosure, performing FEA simulations involved substantial efforts by specialized engineers, which increases the cost of the design process. Additionally, since each FEA model may take a day or more to be constructed by the modeling and simulation engineer, this creates delays and reduces the efficiency of the overall design process. In other words, since designers and operators of a pressure-controlling component are unable to perform FEA modeling themselves, these designers and operators are typically relegated to waiting for the post-processed results of each FEA modeling operation before modifying the design of the component, creating undesired delays and adding substantial cost to the component design process.

### CAE Toolkit for Validation of Pressure-Controlling Component Designs

With the foregoing in mind, some embodiments are directed to a CAE toolkit or other simulation program that enables a user without expert knowledge in FEA simulation and modeling, such as a designer or operator of a pressure-controlling component, to perform a FEA simulation to verify the operation of the component. For example, the disclosed CAE toolkit enables a designer to simulate the shearing process for a BOP shear ram design. The CAE toolkit can be configured to automate the complete modeling and simulation procedure, from model setup to final result generation. Unlike typical FEA modeling, the CAE toolkit only receives simple and generic information on the component design, the application scenario, and the material properties of the system. Since the CAE toolkit does not request that the user provide FEA information, a design engineer without a background or expertise in CAE or FEA can still effectively utilize the CAE toolkit to test designs of pressure-controlling components, and to improve the efficiency of the design process of these components.

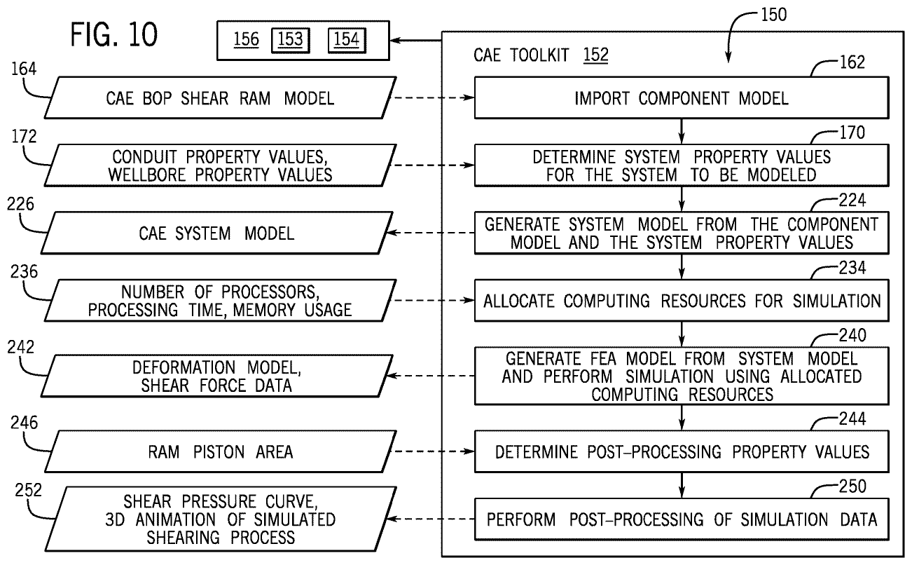

FIG. 10 is a flow diagram illustrating an embodiment of a process 150 whereby the CAE toolkit 152 receives information, performs a simulation based on the received information, and post-processes the results of the simulation. It may be appreciated that the illustrated process 150 is merely an example, and, in other embodiments, the process 150 may include additional steps (e.g., activities, operations, repeated steps, omitted steps, and so forth, in accordance with the present disclosure. Additionally, it may be appreciated that, in certain embodiments, the CAE toolkit 152, including the process 150, may be stored in a suitable computer memory 153 (e.g., random access memory (RAM), hard disk drive, solid state disk drive, optical media) and may be executed by suitable processing circuitry 154 (e.g., a central processing unit (CPU), a graphics processing unit (GPU), a physics processing unit (PPU)) of a computing system 156 (e.g., a server, a workstation, a laptop).

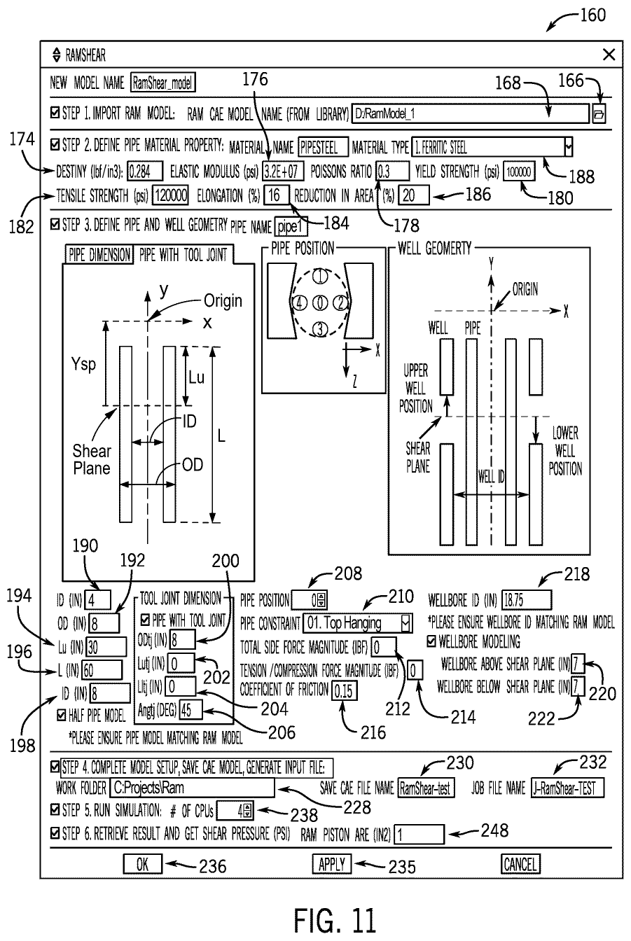

In certain embodiments, the CAE toolkit 152 may include a graphical user interface (GUI) 160, as illustrated in FIG. 11, which guides the user through the process 150 of FIG. 10. The GUI 160 and any of the other information disclosed herein (e.g., the simulation results) may be presented on a display screen of the computing system 156 or otherwise communicatively coupled to the processing circuitry 154 of the computing system 156. To enhance usability, the CAE toolkit 152 may be integrated with CAE software, and the GUI 160 may be written using Python or another suitable programming language. The process 150 of FIG. 10 is discussed with reference to elements of the GUI 160 of the CAE toolkit 152 illustrated in FIG. 11. It may be appreciated that the GUI 160 illustrated in FIG. 11 is merely an example, and in other embodiments, the GUI 160 may include other user input mechanism or have a different organizational layout relative to the embodiment illustrated in FIG. 11. Additionally, while certain aspects of the illustrated process 150 of FIG. 10 and certain elements of the illustrated GUI 160 of FIG. 11 are particular to the design and simulated testing of BOP shear rams, in other embodiments, these aspects and elements may be different to facilitate the design and simulated testing of other pressure-controlling components, in accordance with the present disclosure.

The embodiment of the process 150 illustrated in FIG. 10 begins with the CAE toolkit 152 importing (block 162) a component model 164 of a pressure-controlling component being designed. For the illustrated embodiment, the CAE toolkit 152 receives inputs from a user indicating a CAE BOP shear ram model as the component model 164, which describes a design of both the upper shear ram 50A and the lower shear ram 50B to be tested. In other embodiments, the CAE toolkit 152 may alternatively receive a CAD model of the pressure-controlling component design. It may be noted that, like a CAD model, a CAE model generally describes the various dimensions of the component; however, the CAE may include information regarding the material properties (e.g., yield strength, toughness, elongation) of various portions of the component. Turning briefly to FIG. 11, in step 1, the illustrated embodiment of the GUI 160 of the CAE toolkit 152 includes a navigation button 166 and a corresponding text box 168, which enable the user to select or identify a file containing the component model 164 to be used by the CAE toolkit 152.

Returning to FIG. 10, the process 150 continues with the CAE toolkit 152 determining (block 170) system property values 172 for the system to be modeled and simulated. That is, while the component model 164 may describe the design of and certain material properties of the pressure-controlling component (e.g., BOP shear rams 50), other parameters regarding the simulated system (e.g., the BOP 24, the conduit 20, the wellbore 18, the wellhead 14, the drilling system 10) may be provided to, or otherwise determined by, the CAE toolkit 152. For the illustrated embodiment, to simulate operation of the BOP shear ram design, the CAE toolkit 152 receives system properties values 172 describing the conduit 20 (e.g., material properties, dimensions, geometry, boundary constraints/conditions) and the well (e.g., dimensions, geometry). It may be appreciated that, when designing other pressure-controlling components, other system property values of the system to be simulated may be provided to, or otherwise determined by, the CAE toolkit 152.

Turning to FIG. 11, in step 2, the illustrated embodiment of the GUI 160 of the CAE toolkit 152 includes a number of suitable user input mechanisms (e.g., drop-down lists, text boxes) that enable the CAE toolkit 152 to receive system property values 172 from the user regarding the properties of the conduit 20, including density 174, clastic modulus 176, poisons ratio 178, yield strength 180, tensile strength 182, percent elongation 184, and percent reduction in area 186. In certain embodiments, the user may use a material type drop-down list 188 to select a defined material type, and one or more of the material properties of the selected material type may be automatically populated based on the selected material and stored material property values of the selected material. However, it may be appreciated that the user may customize any of the parameters of the conduit via the GUI 160, for example, to define a conduit 20 having a new material type. It may be appreciated that, in other embodiments, different material properties may be included in step 2 of the GUI 160.

Also in FIG. 11, in step 3, the illustrated embodiment of the GUI 160 of the CAE toolkit 152 includes a number of suitable user input mechanisms (e.g., drop-down lists, check boxes, text boxes) that enable the CAE toolkit 152 to receive system property values 172 from the user regarding the geometry (e.g., dimensions, positions) of the conduit 20 and the wellbore 18. For example, step 3 of the GUI 160 includes a number of input mechanisms to enable the CAE toolkit 152 to receive property values that describe the dimensions of the conduit 20, including an inner diameter 190, an outer diameter 192, a length 194 of the conduit 20 above the shear plane, a total length 196, and a distance 198 from the shear plane to the origin. The GUI 160 also includes number of input mechanisms to enable the CAE toolkit 152 to receive property values that describe the dimensions of a tool joint of the conduit, when present, including an outer diameter 200, a length 202 of the tool joint above the shear plane, a length 204 of the tool joint below the shear plane, and an angle 206 of the tool joint. The GUI 160 also includes number of input mechanisms to enable the CAE toolkit 152 to receive property values describing the other aspects of the conduit 20 and wellbore 18, including a position 208 of the conduit 20 in the wellbore 18, how the conduit 20 is supported in the wellbore 18 (e.g., bottom, top) 210, total side force 212, tension/compression force 214, and coefficient of friction 216. The GUI 160 further includes number of input mechanisms to enable the CAE toolkit 152 to receive property values describing the other aspects of the geometry of the wellbore 18, including an inner diameter 218, a distance 220 that the wellbore 18 is disposed above the shear plane, and a distance 222 that the wellbore is disposed below the shear plane.

Returning to FIG. 10, the process 150 continues with the CAE toolkit 152 generating (block 224) a system model 226 from the component model 164 and the system property values 172. For the illustrated embodiment, the CAE toolkit 152 generates a system model 226 (e.g., a CAE system model) based on the component model 164 (e.g., the CAE BOP shear ram model) and the system property values 172 (e.g., conduit properties and well properties). Unlike the component model 164, the system model 226 describes the relevant aspects of the overall system being simulated, including both the shear rams 50 and the conduit 20. Turning briefly to FIG. 11, in step 4, the illustrated embodiment of the GUI 160 of the CAE toolkit 152 includes a number of suitable user input mechanisms (e.g., text boxes) that enable the CAE toolkit 152 to receive information from the user regarding a location 228 (e.g., in the memory 153 of the computing device 156) in which the system model 226 will be saved, as well as information regarding the file name 230 and job name 232. It may be noted that, when only the checkboxes associated with steps 1, 2, 3, and 4 of the GUI 160 have been selected, upon receiving input from the user to proceed (e.g., via the apply button 235 or OK button 236), the CAE toolkit 152 will generate the system model 226, but will not proceed to the following steps of the process 150 of FIG. 10 discussed below.

Returning again to FIG. 10, the process 150 continues with the CAE toolkit 152 allocating (block 234) computing resources to perform the simulation of the operation of the pressure-controlling component design. For the illustrated embodiment, the CAE toolkit 152 allocates the computing resources based on computation resource input 236 received from the user, which indicates a number of processors to be used, an amount of processing time, a memory usage limit, or any other suitable input regarding computer resources to carry out the simulation. Turning briefly to FIG. 11, in step 5, the illustrated embodiment of the GUI 160 includes a suitable input mechanism (e.g., a text box) that enables the CAE toolkit 152 to receive the computation resource input 236 from the user, namely a number 238 of processors 154 of the computing device 156 that should be used to carry out the simulation. As noted above, the CAE toolkit 152 may only proceed with performing the simulation using the allocated computing resources when the checkbox associated with step 4 is selected. It may be appreciated that, in other embodiments, different computing resources (e.g., a processing time limit, memory usage limit) may be included in step 4 of the GUI 160.

Returning to FIG. 10, the process 150 continues with the CAE toolkit 152 generating (block 240) a FEA model from the system model 226, and then using the FEA model to perform the simulation using the allocated computing resources. For example, the CAE toolkit 152 uses the system model 226 to generate the conduit geometry, assign material properties to the various features, create a fine mesh, and define boundary conditions/constraints of the FEA model. After the simulation is complete, the CAE toolkit 152 outputs a set of simulation results 242. For the illustrated embodiment, the simulation results include simulated shear data and simulated deformation data. For example, the simulation results may include a deformation model and a shear pressure graph based on the simulation. In certain embodiments, the deformation model may be or include a 3D visualization of the deformation and internal strain of the shear rams 50 and the conduit 20 throughout the simulated shearing process. In certain embodiments, the CAE toolkit 152 may create and store files in the manner indicated by the user in step 4 of the GUI 160 illustrated in FIG. 11.

In certain embodiments, the CAE toolkit 152 may also automatically perform post-processing on the simulation results 242. For the embodiment of the process 150 illustrated in FIG. 10, the CAE toolkit 152 determines (block 244) a ram piston area value as a post-processing property value 246 received from the user. Turning briefly to FIG. 11, in step 6, the illustrated embodiment of the GUI 160 includes a suitable input mechanism (e.g., a text box) that enables the CAE toolkit 152 to receive a ram piston area value 248 as a post-processing property value 246. In response to this value being provided and the checkbox associated with step 6 being selected, the CAE toolkit 152 automatically performs post-processing (block 250) of the simulation results 242 based on the received post-processing property value 246. For example, after the simulation is complete, the CAE toolkit 152 may further process the simulation results 242 (e.g., the shear force curve), based on the received post-processing property value 246, to generate post-processed simulation results 252 (e.g., a shear pressure curve). Additionally, in certain embodiments, during post-processing, the CAE toolkit 152 may generate a 3D animation of the simulated shearing process based on the deformation model of the simulation results 242.

It may be appreciated that the CAE toolkit 152 reduces the time involved in setting up and running a FEA simulation of a pressure-controlling component design. That is, while traditional FEA modeling previously involved hours to days of a modeling and simulation engineer's time to configure the simulation, perform the simulation, and post-process the results, the CAE toolkit 152 enables a simulation to be configured in minutes by user, who may be a designer or operator with little or no experience or expertise in FEA modeling. Additionally, the CAE toolkit 152 offers flexibility in that the user can easily adjust and test different conduit positions and boundary constraints, which enables designers optimize the design of a pressure-controlling component by comparing its performance under real and complex well scenarios.

### Example: CAE Toolkit Simulated Testing of BOP Shear Ram Design

The operation of an example BOP shear ram design was tested using the CAE toolkit 152 according to the process 150 illustrated in FIG. 10. It may also be noted that the parameter values illustrated in FIG. 11 correspond to the simulated testing of this example BOP shear ram design. Additionally, the experimental shear pressure data presented in FIG. 5 corresponds to laboratory testing of the same example BOP shear ram design.

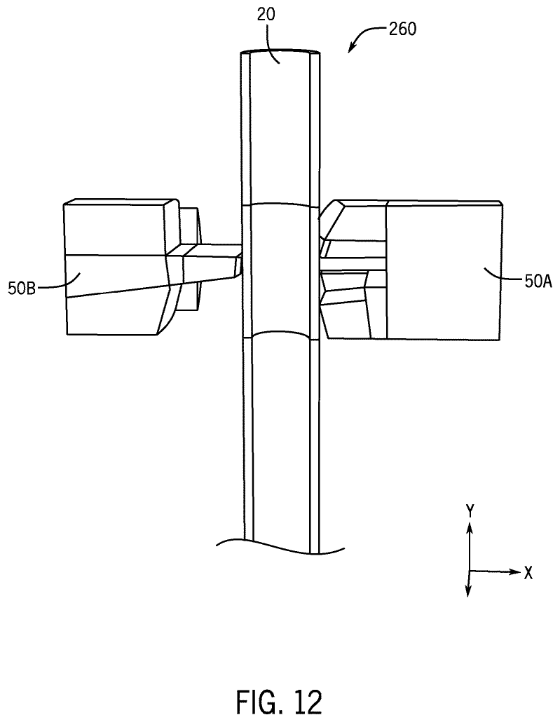

For this example, referring briefly back to FIG. 10, after importing the component model 164 (e.g., the CAE BOP shear ram model) in block 162, and after determining system property values 172 (e.g., conduit properties, well properties) in block 170, the CAE toolkit 152 generates a CAE system model 226. FIG. 12 illustrates an example of a CAE system model 260 generated by the CAE toolkit 152 for this example. For the illustrated embodiment, the CAE system model 226 includes an 8 inch (20.3 centimeter) conduit 20 that is top hanging and is located at the center of the wellbore 18 (not illustrated). The shear ram design, conduit material properties, conduit dimensions, boundary conditions (e.g., orientation of conduit 20, position of the conduit, forces acting on the conduit, how the conduit is supported during the simulation, etc.), and so forth, are provided to the CAE toolkit via the GUI 160, as illustrated in FIG. 11. For this example, because the geometric plane is symmetric, a half model is selected and applied, which reduces the computational time and cost of the simulation. Based on the CAE system model 260 illustrated in FIG. 12, the CAE toolkit 152 automatically creates a FEA model, runs a simulation, generates simulation results, and post-processes the simulation results.

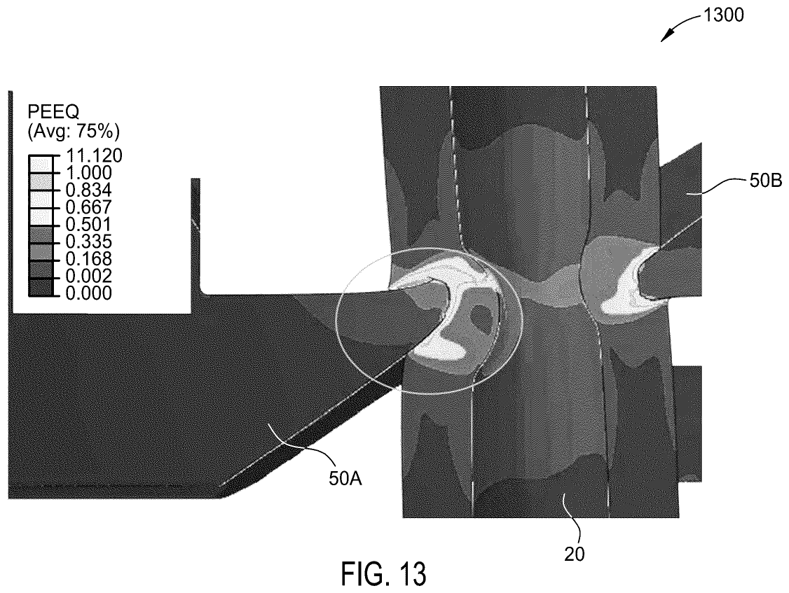

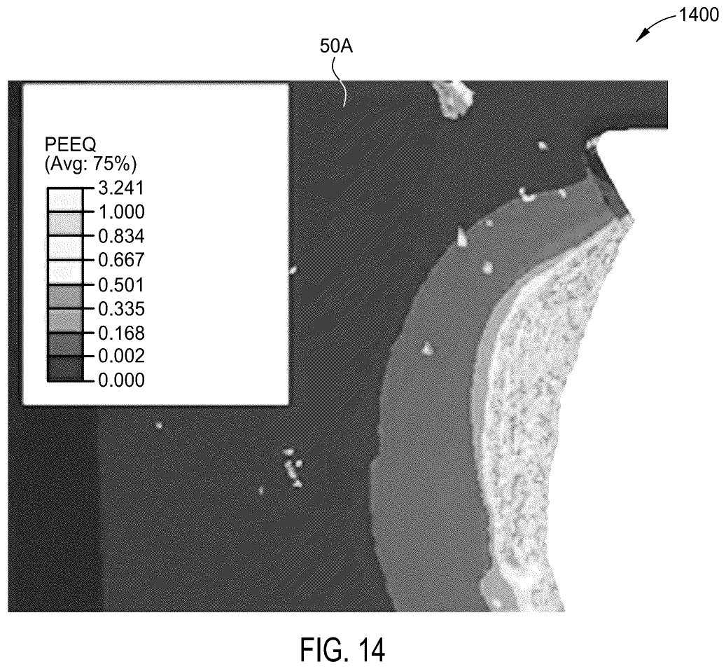

FIGS. 13-15 illustrates embodiments of the post-processed simulation results 252 of the simulated operation of the example BOP shear ram design based on the system property values 172 (e.g., conduit properties, wellbore properties) indicated in FIG. 11. In some embodiments, the post-processed simulation results 252 also include a 3D image or visualization (see FIGS. 13-14) depicting the deformation and internal strain of the conduit or the component model 164 during the simulated shearing process. In certain embodiments, the 3D visualization can be configured to illustrate deformation of only the conduit 20, to illustrate deformation of only the component model 164 (e.g., modeled shear rams 50), or to illustrate the deformation to all of these components at during particular points, and from any desired angle, during the simulated shearing process.

FIG. 13 illustrates a 3D visualization 1300 of a cross-section of the simulated shearing process. As shown, each ram 50A, 50B is engaged with a conduit 20. The 3D visualization 1300 shows a simulated deformation in the rams 50A,B and in the conduit. The 3D visualization 1300 includes a key and corresponding shading to indicate equivalent plastic strain values (PEEQ), which provides a measure of internal strain in the conduit 20 and/or shear rams 50A,B as a result of deformation during the simulated shearing process.

FIG. 14 illustrates a 3D visualization 1400 of a portion of ram 50A during the simulated shearing process. As shown, the 3D visualization 1400 shows a simulated deformation of the ram 50A. The 3D visualization similarly includes a key and corresponding shading to indicate equivalent plastic strain values, which provides a measure of internal strain in the shear rams 50A as a result of deformation during the simulated shearing process

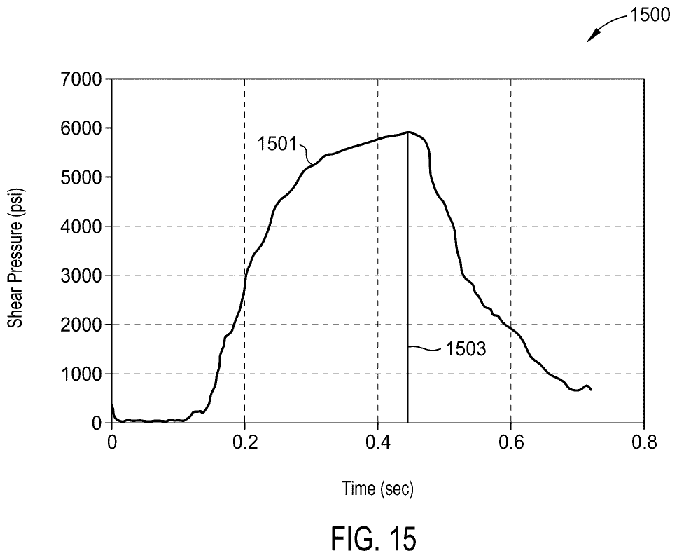

In some embodiments, and as shown in FIG. 15, the post-processed simulation results 252 may include a shear pressure graph 1500 with a shear pressure curve 1501 indicating the pressure applied to the shear rams 50A,B throughout the simulated shearing process. The shear pressure curve 1501 indicates a predicted maximum shearing pressure of 5925 psi.

In some embodiments, the post-processed simulation results 252 may include a 3D animation depicting the shear rams 50A,B and the conduit 20 during the simulated shearing process. The user can move the vertical line 1503 on the graph 1500 to indicate a particular point in time, and the 3D animation and the 3D visualizations 1300, 1400 are automatically updated to present the corresponding information related to that point in time during the simulated shearing process.

The disclosed techniques enable simulated testing of designs of pressure-controlling components for pressure-controlling equipment used in oil and gas applications. The disclosed CAE toolkit automates and integrates the process from computer-aided design (CAD) to simulation of operation, thereby simplifying simulation and enhancing the design optimization process. The CAE toolkit does not require CAE/FEA domain knowledge, which enables the modeling and simulation work to be performed by designers during the design process of a pressure-controlling component. The CAE toolkit also reduces the time involved in configuring, running, and post-processing a simulation from many hours to several minutes. The accuracy of the CAE toolkit method has been verified over a range of different of conduit dimensions and pressures, and demonstrates good agreement with experimental data.

### Automated Redesign of a Component Model

The process 150 described above allows for a user to test a specific component model 164 (e.g., design) against a specific conduit 20 by importing the component model (block 162) and setting the system properties values (block 172) into the GUI 160. In some embodiments, the post-processed simulation results 252 may show that the component model 164 failed the test. For example, the simulated shear data may show that the component model 164 exceeds an acceptable shear pressure threshold. As another example, the simulated deformation data may show that the component model 164 deforms beyond acceptable limits (e.g., a deformation threshold). According to one or more embodiments of the present disclosure, the simulated test results may be analyzed to determine one or more points of failure of the component model 164. The component model 164 may then be redesigned to create an updated component model that is input into CAE toolkit 152 to repeat the process 150. The process 150 may be repeated iteratively to test each updated component model until a component model is generated that passes the test.

In some embodiments, a component model 164 (e.g., CAE model, CAD model) is iteratively redesigned based on a conduit pool (e.g., pipe pool) input into a simulation program, such as the CAE toolkit 152. The conduit pool may be stored in the memory 153. The conduit pool includes one or more conduits (e.g., pipes, tubulars), such as three or more conduits. Each conduit in the conduit pool may be selected based on different conduits, including other equipment such as wirelines and braided cable, that is expected to be used in combination with the component model when deployed in the field. Each conduit in the conduit pool has one or more properties. In other words, each conduit in the conduit pool may have different material properties, dimensions, geometry, and boundary constraints/conditions. In some embodiments, the conduit pool may have multiple conduits that are the same but have different boundary conditions. The conduit pool is used to generate the CAE system model 226 that is used generate a FAE model to test the design. For example, a conduit in the pool is paired with the input component model to generate a CAE system model 226 that is then tested to generate simulated shear data and simulated deformation data. The system property values 172, which are based on the simulated conduit and the simulated well, is used to generate the CAE system model 226. The system property values 172 may be stored in the memory 153. The system property values 172 are based on the conduit pool and various wells and well conditions. In other words, the memory 153 may include a plurality of system property values 172, each one being a combination of one conduit in the conduit pool, the one or more properties of the conduit, and the well properties. Each system property value 172 may be used to generate a CAE system model 226 in combination with the input component model 164.

The input component model 164 is iteratively tested against each conduit in the conduit pool. If the input component model fails the test with respect to any conduit in the conduit pool, such as having unsatisfactory simulated shear data or simulated deformation data, then the component model is deemed failed. The testing may stop when a failure is detected, or the testing may continue until the component model is tested against every conduit in the conduit pool. The iterative testing may be done automatically by the CAE toolkit 152 or other simulation program. In other words, the simulation program may when prompted conduct each simulated test of the component design against the conduit pool until a failure occurs or the component design passes the test with respect to every conduit in the conduit pool. When a failure is determined, the user interface may display which conduit in the conduit pool prompted the failure along with the test conditions. The CAE toolkit 152 may also output the post-processing simulation data 250, such as a shear pressure curve or 3D visualization of the deformation of the conduit and/or component model. The user may use the post-processing simulation data 250 to identify one or more points of failure of the component model 164. For example, the post-processing simulation data 250 may reveal that a portion of the component model 164 has an inadequate thickness or area of contact with the conduit due to the deformation data. The user may than update the design of the component model 164. The updated design may then be iteratively tested against the conduit pool. This process continues until a design of the component model passes the test with respect to each conduit in the conduit pool. The passing design may then be selected for laboratory testing.

In some embodiments, the simulation program itself is able to identify one or more points of failure of the component model 164. The simulation program then changes the design of the component model 164 to create an updated component model based on one or more design or modeling parameters. The simulation program then iteratively tests the updated component model design against the conduit pool and continuously updates the design until a passing design is created. The passing design may then be output to the user for review and/or preparation for laboratory testing. The simulation program may automatically, when prompted by the user (e.g., such as by pressing OK button 236), test and update the design of the component model until a passing design is determined without additional input by the user.

Multiple passing pressure-control component designs may be generated according to embodiments described herein. One or more designs may be selected for laboratory testing based on the materials cost. For example, a first passing design may be made of a first material that is cheaper than a second material used in a second passing design. The first passing design may be selected for testing based on the materials cost. Additionally, the simulation program may automatically test a passing design with respect to various materials, to determine which materials would likely pass the laboratory test.

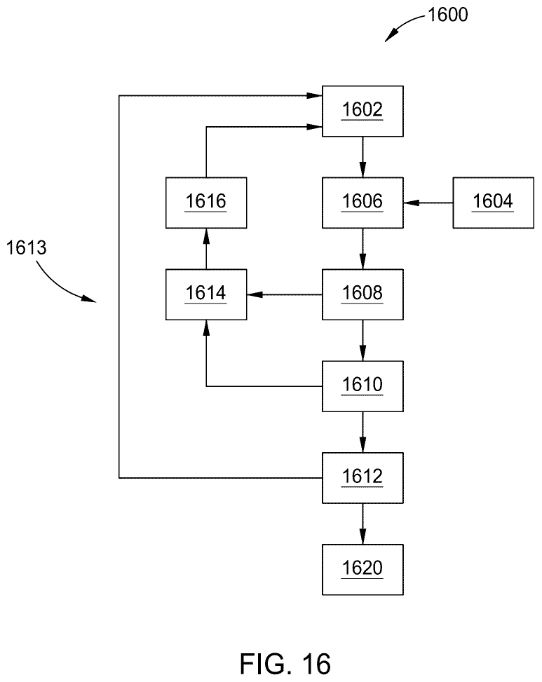

FIG. 16 illustrates a flowchart of an exemplary method 1600 of automatically designing a pressure-control component, such as a shear ram 50, with a simulation program to generate a design worth of laboratory testing.

At activity 1602, an initial component model is input into the simulation program, such as CAE toolkit 152. Additionally, test conditions may also be input into the simulation program. For example, the wellbore properties may be input into the simulation program.

At activity 1604, a conduit pool is input into the simulation program. The conduit pool may be selected based on the type of pressure control component being designed. In some embodiments, the conduit pool is pre-input (e.g., stored in the memory 153) of the simulation program and is used to test each design input into the simulation program against the conduit pool. For example, each conduit in the conduit pool may have data stored that automatically populates Step 3 of the process 150 as shown on the GUI interface 160 in FIG. 11. In some embodiments, the conduit pool is application specific and is input by the user to facilitate designing a pressure-control component for a specific application.

At activity 1606, the simulation program then test the input component model against the conduit pool. Each test may include automatically conducting process 150 based on the input component model and the conduit in the conduit pool being tested without further input from the user. For example, the initial component model and the system property values 172 associated with the conduit being tested are used to generate an FEA model (see block 240). The FEA model of the design is tested based on a simulated operation of the design. The simulated operation is analyzed to output simulated shear data and simulated deformation data.

Activities 1608 and 1610 relate to analyzing the output simulated shear data and simulated deformation data to determine if the input design passed the test with respect to the conduit of the conduit pool being tested. In some embodiments, if the design fails Activity 1608, then the method 1600 proceeds to Activity 1614 without proceeding to Activity 1610. In some embodiments, Activity 1610 occurs prior to Activity 1608, and if the design fails Activity 1610, then the method 1600 proceeds to Activity 1614 without proceeding to Activity 1608. In some embodiments, the method 1600 includes performing both Activities 1608, 1610 even if the design fails the one performed first. However, a failure of either Activity 1608 or 1610 results in the method proceeding to Activity 1614.

As an example, Activity 1608 involves analyzing the simulated shear data to determine if the input design failed the test. For example, Activity 1608 may include generating a shear pressure curve (see FIG. 15) and determining the maximum simulated shear pressure. The maximum simulated shear pressure is then compared to a threshold. If the maximum simulated shear pressure exceeds the shear pressure threshold (e.g., shear pressure objective), then the input component design failed the test.

As an example, Activity 1610 involves analyzing the simulated deformation data to determine if the input design failed the test. For example, Activity 1610 may include generating a 3D visualization of the component design and conduit, such as the 3D visualizations 1300 and 1400. In some embodiments, the simulation program may determine that the test failed if a portion of the input component design deforms beyond an allowable limit (e.g., deformation threshold, deformation objective). In some embodiments, the simulation program analyzes the PEEQ occurring during the test and determines that the test failed when the PEEQ exceeds a threshold. In some embodiments, the simulation program may determine that the test failed if the volume of the input component design changes beyond an allowable limit. The simulation program may also use other suitable metrics to determine that the test was failed based on the simulated deformation data.

The method 1600 proceeds to Activity 1612 if the design passes the test (e.g., Activities 1608, 1610) with respect to an individual conduit of the conduit pool. At Activity 1612, the simulation program determines if the design has been tested and passed the test for every conduit in the conduit pool. If the design has not been tested with respect to one or more conduits, then the design is then input back into the simulation program for further testing against a different conduits in the conduit pool as shown by Activity 1613. Each design is tested against each conduit in the conduit pool in sequence. If the design fails with respect to a different conduit in the conduit pool, then the design is analyzed in Activity 1614 and redesigned in Activity 1616 and then tested against every conduit in the conduit pool until a design is reached that passes the test with respect to every conduit in the conduit pool. In other words, a failure of the design with respect to any conduit in the conduit pool results in subsequent analysis to redesign the component design and subsequent testing of the updated design against each conduit in the conduit pool. If the design has passed the test with respect to each conduit in the pipe pool, then a passing design is output as shown as Activity 1620. If the passing design is a candidate for laboratory testing.

At Activity 1614, the input component design is analyzed to determine one or more points of failure if the input component design fails the test, such as being deemed a failure under Activity 1608 and/or Activity 1610. The simulated shear data and simulated deformation data are analyzed to determine one or more points of failure of the input component design. For example, the maximum simulated shear may be indicative of an insufficient surface area of the input design. For example, the simulated deformation data may be used to identify one or more portions of the input component design that deformed beyond an allowable limit. The simulation program may determine that one or more of these portions have an insufficient material thickness. The simulation program may also determine that the material of the input design needs to be changed.

At Activity 1616, the simulation program, based on the simulated shear and/or the simulated deformation data, updates the design of the input component model. In some embodiments, the simulation program updates the input design by changing the underling CAD model or CAE model of the input design based on the one or more points of identified failure. For example, the simulation program may increase the thickness of one or more portions of the component model if thickness was identified as a point of failure. Similarly, the simulation program may change adjust the area, such as increase the area, of the portion of the component model that contacts the conduit based on the simulated shear data. In some embodiments, the simulation program changes one or more materials of the component design, such as selecting a material to compensate for the simulated deformation. In some embodiments, the simulation program uses the identified one or more points of failure and other test parameters to identify a design in a component library that may overcome the deficiencies of the current design. This design selected from the library may be then be used as the updated design. The method 1600 repeats with the updated component model being input at Activity 1602.

In some embodiments, Activity 1614 includes prompting a user for input. For example, the mode of failure of the design may require user input and analysis. The user may then adjust the design manually and input the updated design into the simulation program for continued iterative testing and updates to the component model design.

As an example, a ram design may be tested against a conduit pool including at least a first conduit and a second conduit of the conduit pool each having one or more properties. A first ram design is input into the simulation program at activity 1602. The conduit pool is input into the simulation program at 1604. At Activity 1606, the first ram design is tested with respect to the first conduit in the conduit pool using the simulation program. The test includes generating a first FEA model based on the one or more properties of the first conduit and the first ram design. The test further includes simulating an operation of the first ram design using the first finite element analysis model to generate first simulated shear data and first simulated deformation data. The test further includes determining if the second design passes the test at Activities 1608 and 1610. In this example, the test determined that the first ram design fails when at least one of the first simulated maximum shear pressure exceeded a shear pressure threshold at Activity 1608 or the first simulated deformation data exceeded a deformation threshold at Activity 1608. At Activity 1614, the simulated shear data and/or the simulated deformation data are analyzed to identify one or more points of failure of the ram design at Activity 1614. Activity 1614 may include, for example, determining that a first simulated deformation occurs at a first portion of the ram design, determining that a thickness of the first portion is insufficient based on the first simulated deformation, and identifying the thickness as a point of failure. At activity 1616, the first ram design is updated to create a second ram design that is then automatically tested with respect to the first conduit in the conduit pool using the simulation program. The method 1600 may repeat to test the second ram design automatically without intervention by the user.

The method 1600 repeats by automatically testing the second ram design at Activity 1606. The test includes inputting the second ram design into the simulation program. The test includes generating a second FEA model based on the one or more properties of the first conduit in the conduit pool and the second ram design. The test further includes simulating an operation of the second ram design using the second FEA model to generate second simulated shear data and second simulated deformation data. The test further includes determining if the second design passes the test at Activities 1608 and 1610.

As one example, the second design passed the shear evaluation at Activity 1608 and the deformation evaluation at 1610. Thus, the second design is then input back into the shear simulation program at activity 1613 to test the second design against the second conduit. If the second design passes the test with respect to the second conduit, then the second design is output as a passing design at Activity 1620.

As one example, the second design failed the shear evaluation at Activity 1608 and/or the deformation evaluation at 1610. The second design is then analyzed at Activity 1614 to identify one or more points of failure of the second design. The second design is then updated to create a third design based on the identified one or more points of failure. The third design is then input into the simulation program to be tested against the first conduit prior to testing against the second conduit to ensure that the changes do result in a failure with respect to the first conduit. Third simulated shear data and third simulated deformation data are generated during the test and used to evaluate the third design. The third design is redesigned again based on one or more identified points of failure if a test is failed. The design is updated until passable design is found that passes the test with respect to all conduits in the conduit pool.

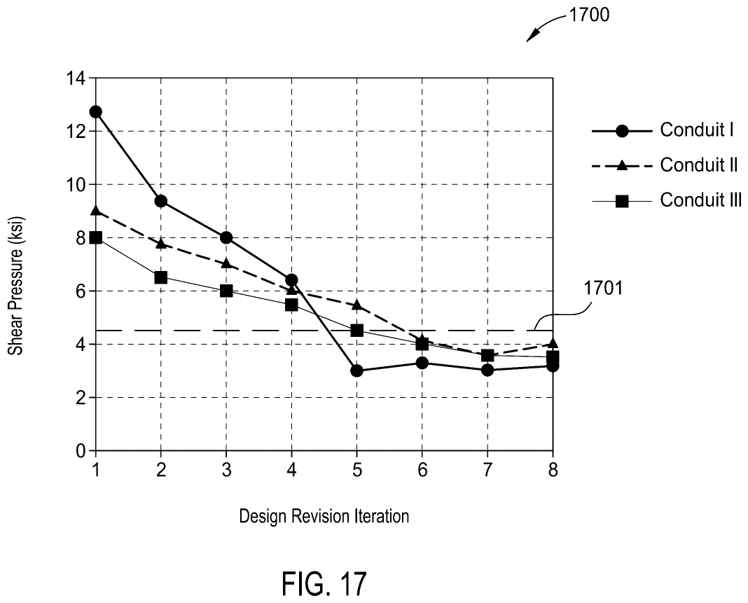

Development time is reduced using this automated method of redesigning the component model. FIG. 17 illustrates shear pressure results across eight design iterations of a shear ram designed according to method 1600. Each design iteration was tested against three conduits in a conduit pool. As shown, six design iterations were required to achieve a ram design that did not exceed the shear pressure threshold shown as line 1701. Reducing the design iterations shortens the development timeline further to create a design worth of the time and resources required for laboratory testing.

Designs that pass laboratory testing may be input into a library of component designs that can be used as a resource for future component designs based on a desired application by a customer. For example, a component design may be selected from the library and tested by the simulation program to determine if the design is likely to pass laboratory testing for the desired customer application. If the design fails the simulated testing for the desired customer application, then the design may be redesigned using method 1600 to create a new design that is worthy of a laboratory test.

The simulation program, such as the CAE toolkit, may include a programmable central processing unit (“CPU”) which is operable with a memory (e.g., non-transitory computer readable medium and/or non-volatile memory) and support circuits. For example, in one or more embodiments the CPU is one of any form of general purpose computer processor used in an industrial setting, such as a programmable logic controller (“PLC”), for controlling various polishing system components and sub-processors. The memory, coupled to the CPU, is non-transitory and is one or more of readily available memory such as random access memory (“RAM”), read only memory (“ROM”), floppy disk drive, hard disk, or any other form of digital storage, local or remote.

Herein, the memory is in the form of a computer-readable storage media containing instructions (e.g., non-volatile memory), that when executed by the CPU, facilitates the generation of the 1-D MEM and the proxy MEM. The instructions in the memory are in the form of a program product such as a program that implements the methods of the present disclosure (e.g., middleware application, equipment software application, etc.). The program code may conform to any one of a number of different programming languages. In one or more embodiments, the disclosure may be implemented as a program product stored on computer-readable storage media for use with a computer system. The program(s) of the program product define functions of the embodiments (including the methods and operations described herein).

Illustrative computer-readable storage media include, but are not limited to: (i) non-writable storage media (e.g., read-only memory devices within a computer such as CD-ROM disks readable by a CD-ROM drive, flash memory, ROM chips or any type of solid-state non-volatile semiconductor memory) on which information is permanently stored; and (ii) writable storage media (e.g., floppy disks within a diskette drive or hard-disk drive or any type of solid-state random-access semiconductor memory) on which alterable information is stored. Such computer-readable storage media, when carrying computer-readable instructions that direct the functions of the methods described herein, are embodiments of the present disclosure.

The various methods (such as process 150 or method 1600) and operations (such as Activities 1602-1620) disclosed herein may generally be implemented under the control of the CPU by the CPU executing computer instruction code stored in the memory as, e.g., a software routine. When the computer instruction code is executed by the CPU, the CPU conducts operations in accordance with the various methods and operations described herein. In one or more embodiments, the memory (a non-transitory computer readable medium) includes instructions stored therein that, when executed, cause the method (such as the method 1600) and operations (such as Activities 1602-1620) described herein to be conducted. The operations described herein can be stored in the memory in the form of computer readable logic.

It is contemplated that any operation, activity, or example related to the process 150 may be incorporated into the method 1600. It is further contemplated that any operation, activity, or example related to the method 1600 may be incorporated into the process 150.

### Example Aspects

Implementation examples are described in the following numbered aspects:

Aspect 1: A method of designing a ram, comprising: inputting a first ram design into a simulation program; inputting a conduit pool into the simulation program, the conduit pool including a first conduit and one or more properties of the first conduit; automatically testing the first ram design with respect to the first conduit in the conduit pool using the simulation program, the testing including: generating a first finite element analysis model based on the one or more properties of the first conduit and the first ram design; simulating an operation of the first ram design using the first finite element analysis model to generate a first simulated maximum shear pressure and a first simulated deformation; and determining that the first ram design failed the test when at least one of the first simulated maximum shear pressure exceeds a shear pressure threshold or the first simulated deformation exceeds a deformation threshold; and modifying the first ram design to create a second ram design after determining that the first ram design failed the test; and automatically testing the second ram design with respect to the first conduit in the conduit pool using the simulation program.

Aspect 2: The method of Aspect 1, wherein automatically testing the second ram design includes comprises: inputting the second ram design into the simulation program; generating a second finite element analysis model based on the one or more properties of the first conduit in the conduit pool and the second ram design; simulating an operation of the second ram design using the second finite element analysis model to generate a second simulated maximum shear pressure and a second simulated deformation; and determining that the second ram design passed the test when the second simulated maximum shear pressure is less than the shear pressure threshold and the second simulated deformation is less than the deformation threshold.

Aspect 3: The method of Aspect 2, further comprising: automatically testing the second ram design with respect to a second conduit in the conduit pool using the simulation program, the testing including: generating a third finite element analysis model based on one or more properties of the second conduit and the second ram design; and simulating an operation of the second ram design using the third finite element analysis model to generate a third simulated maximum shear pressure and a third simulated deformation.

Aspect 4. The method of Aspect 3, wherein automatically testing the second ram design with respect to the second conduit in the conduit pool further comprises determining that the second ram design failed the test when at least one of the third simulated maximum shear pressure exceeds the shear pressure threshold or the third simulated deformation exceeds the deformation threshold; and modifying the second ram design to create a third ram design after determining that the second ram design failed the test.

Aspect 5: The method of Aspect 3, wherein automatically testing the second ram design with respect to the second conduit in the conduit pool further comprises determining that the second ram design passed the test when the third simulated maximum shear pressure is less than the shear pressure threshold and the third simulated deformation is less than the deformation threshold.

Aspect 6: The method of Aspect 5, further comprising: determining that a material cost of the second ram design exceeds a material cost of a different ram design that passed the automatic testing; and selecting the different design for laboratory testing.

Aspect 7: The method of any combination of Aspects 1-6, wherein modifying the first ram design to create the second ram design comprises using the simulation program to automatically: analyze at least one of simulated shear pressure data or the first simulated deformation collected during the test of the first ram design using the simulation program; identify one or more points of failure of the first ram design based on the analysis of the at least one of simulated shear pressure data or first simulated deformation; and modify first ram design to create the second ram design based on the at least one or more identified points of failure of the first ram design.

Aspect 8: The method of Aspect 7, wherein analyzing the simulated deformation data includes: determining that the first simulated deformation occurs at a first portion of the ram design; determining that a thickness of the first portion is insufficient based on the first simulated deformation; and identifying the thickness as a point of failure.

Aspect 9: The method of Aspect 8, wherein modifying the first ram design to create the second ram design includes increasing the thickness of the first portion of the ram design.

Aspect 10: The method of any combination of Aspects 1-9, wherein the first conduit is a braided cable or a wireline.

Aspect 11: A non-transitory, computer-readable medium storing instructions of a simulation program executable by a processor of a computer system, the instructions comprising: testing, for a first time, a first ram design input into the processor with respect to a first conduit in a conduit pool input into the processor using the simulation program, the testing including: generating a first finite element analysis model based on the first ram design and one or more properties of the first conduit; simulating an operation of the first ram design using the first finite element analysis model to generate first simulated shear pressure data and first simulated deformation data, the first simulated shear pressure data includes a first maximum simulated shear pressure and the first simulated deformation data includes a first simulated deformation; determining that: the first ram design failed the first test when at least one of a first simulated maximum shear pressure exceeds a shear pressure threshold or the first simulated deformation exceeds a deformation threshold; or that the first ram design passed the first test when the first simulated maximum shear pressure is less than the shear pressure threshold and the first simulated deformation is less than the deformation threshold; and testing, for a second time, the first ram design with respect to a second conduit in the conduit pool input into the processor using the simulation program upon determining that the first ram passed the first test; and modifying the first ram design to create a second ram design after determining that the first ram design failed the first test and testing the second ram design with respect to the first conduit in the conduit pool.

Aspect 12: The medium of Aspect 11, wherein testing of the first ram design a second time comprises: generating a second finite element analysis model based on the first ram design and one or more properties of the second conduit; simulating an operation of the first ram design using the second finite element analysis model to generate second simulated shear pressure data and second simulated deformation data, the second simulated shear pressure data includes a second maximum simulated shear pressure and the second simulated deformation data includes a second simulated deformation; and determining that: the first ram design failed the second test when at least one of a first simulated maximum shear pressure exceeds the shear pressure threshold or the second simulated deformation exceeds the deformation threshold; or that the first ram design passed the second test when the second simulated maximum shear pressure is less than the shear pressure threshold and the second simulated deformation is less than the deformation threshold.

Aspect 13: The medium of any combination of Aspect 11-12, further comprising: modifying the first ram design to create a second ram design after determining that the first ram design failed the second test and testing the second ram design with respect to the first conduit in the conduit pool.

Aspect 14: The medium of any combination of Aspect 11-13, wherein testing the second ram design a first time with respect to the first conduit using the simulation program, the testing including: generating a second finite element analysis model based on the second ram design and the one or more properties of the first conduit; simulating an operation of the second ram design using the second finite element analysis model to generate second simulated shear pressure data and second simulated deformation data, the second simulated shear pressure data includes a second maximum simulated shear pressure and the second simulated deformation data includes a second simulated deformation; determining that: the second ram design failed the first test when at least one of a second simulated maximum shear pressure exceeds the shear pressure threshold or the second simulated deformation exceeds the deformation threshold; or that the second ram design passed the first test when the second simulated maximum shear pressure is less than the shear pressure threshold and the second simulated deformation is less than the deformation threshold.

Aspect 15: The medium of any combination of Aspects 11-14, further comprising: modifying the second ram design to create a third ram design after determining that the second ram design failed the first test and testing the third ram design with respect to the first conduit in the conduit pool.

Aspect 16: The medium of any combination of Aspects 11-15, wherein the first conduit is a braided cable or a wireline.

Aspect 17: A non-transitory, computer-readable medium storing instructions of a simulation program executable by a processor of a computer system, the instructions comprising: receiving an first ram design; receiving a conduit pool, the conduit pool including one or more properties of a plurality of conduits; changing the first ram design to output a second ram design, comprising: testing the first ram design against the conduit pool, wherein the first ram design fails the test if a first maximum simulated shear pressure exceeds a shear pressure threshold or a first simulated deformation exceeds a deformation threshold for any of the conduits in the conduit pool, the test including: generating a first finite element analysis model based on one conduit in the conduit pool and the first ram design; and simulating an operation of the first ram design using the first finite element analysis model to generate first simulated shear pressure data and first simulated deformation data, the first simulated shear pressure data includes the first simulated maximum shear pressure and the first simulated deformation data includes the first simulated deformation; and analyzing at least one of the first simulated shear pressure data or the first simulated deformation data; identifying one or more points of failure of the first ram design based on the analysis of the at least one of simulated shear pressure data or first simulated deformation data; and modifying the first ram design to create the second ram design based on the at least one or more identified points of failure of the first ram design.

Aspect 18: The medium of Aspect 17, changing the second ram design to output a third ram design, comprising: testing the second ram design against the conduit pool, wherein the second ram design fails the test if a second maximum simulated shear pressure exceeds the shear pressure threshold or a second simulated deformation exceeds the deformation threshold for any of the conduits in the conduit pool, the test including: generating a second finite element analysis model based on one conduit in the conduit pool and the second ram design; simulating an operation of the second ram design using the second finite element analysis model to generate second simulated shear pressure data and second simulated deformation data, the second simulated shear pressure data includes the second simulated maximum shear pressure and the second simulated deformation includes the second simulated deformation; and analyzing at least one of the second simulated shear pressure data or the second simulated deformation data; identifying one or more points of failure of the second ram design based on the analysis of the at least one of the second simulated shear pressure data or the second simulated deformation data; and modifying the second ram design to create the third ram design based on the at least one or more identified points of failure of the second ram design.

Aspect 19: The medium of any combination of Aspects 17-18, wherein the conduit pool includes at least one of a braided cable or a wireline.

Aspect 20: The medium of any combination of Aspects 17-19, wherein the one or more identified points of failure includes an insufficient thickness of a portion of the first ram design, and wherein modifying the first ram design to create the second ram design includes increasing the thickness of the portion of the ram design.

It is contemplated that any one or more elements or features of any one disclosed embodiment or example may be beneficially incorporated in any one or more other non-mutually exclusive embodiments or examples. While the foregoing is directed to embodiments of the present disclosure, other and further embodiments of the disclosure may be devised without departing from the basic scope thereof, and the scope thereof is determined by the claims that follow.

The following claims are not intended to be limited to the aspects shown herein, but are to be accorded the full scope consistent with the language of the claims. Within a claim, reference to an element in the singular is not intended to mean “one and only one” unless specifically so stated, but rather “one or more.” Unless specifically stated otherwise, the term “some” refers to one or more. No claim element is to be construed under the provisions of 35 U.S.C. § 112 (f) unless the element is expressly recited using the phrase “means for”. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims.

What is claimed is:

1. A method of designing a ram, comprising:
inputting a first ram design into a simulation program;
inputting a conduit pool into the simulation program, the conduit pool including a first conduit and one or more properties of the first conduit;
automatically testing the first ram design with respect to the first conduit in the conduit pool using the simulation program, the testing including:
generating a first finite element analysis model based on the one or more properties of the first conduit and the first ram design;
simulating an operation of the first ram design using the first finite element analysis model to generate a first simulated maximum shear pressure and a first simulated deformation; and
determining that the first ram design failed the test when at least one of the first simulated maximum shear pressure exceeds a shear pressure threshold or the first simulated deformation exceeds a deformation threshold;
modifying the first ram design to create a second ram design after determining that the first ram design failed the test; and
automatically testing the second ram design with respect to the first conduit in the conduit pool using the simulation program.

2. The method of claim 1, wherein automatically testing the second ram design includes comprises:
inputting the second ram design into the simulation program;
generating a second finite element analysis model based on the one or more properties of the first conduit in the conduit pool and the second ram design;
simulating an operation of the second ram design using the second finite element analysis model to generate a second simulated maximum shear pressure and a second simulated deformation; and
determining that the second ram design passed the test when the second simulated maximum shear pressure is less than the shear pressure threshold and the second simulated deformation is less than the deformation threshold.

3. The method of claim 2, further comprising:
automatically testing the second ram design with respect to a second conduit in the conduit pool using the simulation program, the testing including:
generating a third finite element analysis model based on one or more properties of the second conduit and the second ram design; and
simulating an operation of the second ram design using the third finite element analysis model to generate a third simulated maximum shear pressure and a third simulated deformation.

4. The method of claim 3, wherein automatically testing the second ram design with respect to the second conduit in the conduit pool further comprises determining that the second ram design failed the test when at least one of the third simulated maximum shear pressure exceeds the shear pressure threshold or the third simulated deformation exceeds the deformation threshold; and
modifying the second ram design to create a third ram design after determining that the second ram design failed the test.

5. The method of claim 3, wherein automatically testing the second ram design with respect to the second conduit in the conduit pool further comprises determining that the second ram design passed the test when the third simulated maximum shear pressure is less than the shear pressure threshold and the third simulated deformation is less than the deformation threshold.

6. The method of claim 5, further comprising:
determining that a material cost of the second ram design exceeds a material cost of a different ram design that passed the automatic testing; and
selecting the different design for laboratory testing.

7. The method of claim 1, wherein modifying the first ram design to create the second ram design comprises using the simulation program to automatically:
analyze at least one of simulated shear pressure data or the first simulated deformation collected during the test of the first ram design using the simulation program;
identify one or more points of failure of the first ram design based on the analysis of the at least one of simulated shear pressure data or first simulated deformation; and
modify first ram design to create the second ram design based on the at least one or more identified points of failure of the first ram design.

8. The method of claim 7, wherein analyzing the simulated deformation data includes:
determining that the first simulated deformation occurs at a first portion of the ram design;
determining that a thickness of the first portion is insufficient based on the first simulated deformation; and
identifying the thickness as a point of failure.

9. The method of claim 8, wherein modifying the first ram design to create the second ram design includes increasing the thickness of the first portion of the ram design.

10. The method of claim 1, wherein the first conduit is a braided cable or a wireline.

11. A non-transitory, computer-readable medium storing instructions of a simulation program executable by a processor of a computer system, the instructions comprising:
testing, for a first time, a first ram design input into the processor with respect to a first conduit in a conduit pool input into the processor using the simulation program, the testing including:
generating a first finite element analysis model based on the first ram design and one or more properties of the first conduit;
simulating an operation of the first ram design using the first finite element analysis model to generate first simulated shear pressure data and first simulated deformation data, the first simulated shear pressure data includes a first maximum simulated shear pressure and the first simulated deformation data includes a first simulated deformation; and
determining that:
the first ram design failed the first test when at least one of a first simulated maximum shear pressure exceeds a shear pressure threshold or the first simulated deformation exceeds a deformation threshold; or
that the first ram design passed the first test when the first simulated maximum shear pressure is less than the shear pressure threshold and the first simulated deformation is less than the deformation threshold; and
testing, for a second time, the first ram design with respect to a second conduit in the conduit pool input into the processor using the simulation program upon determining that the first ram passed the first test; and
modifying the first ram design to create a second ram design after determining that the first ram design failed the first test and testing the second ram design with respect to the first conduit in the conduit pool.

12. The medium of claim 11, wherein testing of the first ram design a second time comprises:
generating a second finite element analysis model based on the first ram design and one or more properties of the second conduit;
simulating an operation of the first ram design using the second finite element analysis model to generate second simulated shear pressure data and second simulated deformation data, the second simulated shear pressure data includes a second maximum simulated shear pressure and the second simulated deformation data includes a second simulated deformation; and
determining that:
the first ram design failed the second test when at least one of a first simulated maximum shear pressure exceeds the shear pressure threshold or the second simulated deformation exceeds the deformation threshold; or
that the first ram design passed the second test when the second simulated maximum shear pressure is less than the shear pressure threshold and the second simulated deformation is less than the deformation threshold.

13. The medium of claim 12, further comprising:
modifying the first ram design to create a second ram design after determining that the first ram design failed the second test and testing the second ram design with respect to the first conduit in the conduit pool.

14. The medium of claim 11, wherein testing the second ram design a first time with respect to the first conduit using the simulation program, the testing including:
generating a second finite element analysis model based on the second ram design and the one or more properties of the first conduit;
simulating an operation of the second ram design using the second finite element analysis model to generate second simulated shear pressure data and second simulated deformation data, the second simulated shear pressure data includes a second maximum simulated shear pressure and the second simulated deformation data includes a second simulated deformation;
determining that:
the second ram design failed the first test when at least one of a second simulated maximum shear pressure exceeds the shear pressure threshold or the second simulated deformation exceeds the deformation threshold; or
that the second ram design passed the first test when the second simulated maximum shear pressure is less than the shear pressure threshold and the second simulated deformation is less than the deformation threshold.

15. The medium of claim 14, further comprising:
modifying the second ram design to create a third ram design after determining that the second ram design failed the first test and testing the third ram design with respect to the first conduit in the conduit pool.

16. The medium of claim 11, wherein the first conduit is a braided cable or a wireline.

17. A non-transitory, computer-readable medium storing instructions of a simulation program executable by a processor of a computer system, the instructions comprising:
receiving an first ram design;
receiving a conduit pool, the conduit pool including one or more properties of a plurality of conduits;
changing the first ram design to output a second ram design, comprising:
testing the first ram design against the conduit pool, wherein the first ram design fails the test if a first maximum simulated shear pressure exceeds a shear pressure threshold or a first simulated deformation exceeds a deformation threshold for any of the conduits in the conduit pool, the test including:
generating a first finite element analysis model based on one conduit in the conduit pool and the first ram design; and
simulating an operation of the first ram design using the first finite element analysis model to generate first simulated shear pressure data and first simulated deformation data, the first simulated shear pressure data includes the first simulated maximum shear pressure and the first simulated deformation data includes the first simulated deformation; and
analyzing at least one of the first simulated shear pressure data or the first simulated deformation data;
identifying one or more points of failure of the first ram design based on the analysis of the at least one of simulated shear pressure data or first simulated deformation data; and
modifying the first ram design to create the second ram design based on the at least one or more identified points of failure of the first ram design.

18. The medium of claim 17, changing the second ram design to output a third ram design, comprising:
testing the second ram design against the conduit pool, wherein the second ram design fails the test if a second maximum simulated shear pressure exceeds the shear pressure threshold or a second simulated deformation exceeds the deformation threshold for any of the conduits in the conduit pool, the test including:
generating a second finite element analysis model based on one conduit in the conduit pool and the second ram design;
simulating an operation of the second ram design using the second finite element analysis model to generate second simulated shear pressure data and second simulated deformation data, the second simulated shear pressure data includes the second simulated maximum shear pressure and the second simulated deformation includes the second simulated deformation; and
analyzing at least one of the second simulated shear pressure data or the second simulated deformation data;
identifying one or more points of failure of the second ram design based on the analysis of the at least one of the second simulated shear pressure data or the second simulated deformation data; and
modifying the second ram design to create the third ram design based on the at least one or more identified points of failure of the second ram design.

19. The medium of claim 17, wherein the conduit pool includes at least one of a braided cable or a wireline.

20. The medium of claim 17, wherein the one or more identified points of failure includes an insufficient thickness of a portion of the first ram design, and wherein modifying the first ram design to create the second ram design includes increasing the thickness of the portion of the ram design.
